(19) United States
(12) Patent Application Publication
(10) Pub. No.: US 2024/0371986 A1
(43) Pub. Date: Nov. 7, 2024

(54) QUANTUM DEVICE INCLUDING MODERATE FLUORIATED GRAPHENE AND METHOD FOR FABRICATING SAME

(71) Applicant: POSTECH RESEARCH AND BUSINESS DEVELOPMENT FOUNDATION, Pohang-si (KR)

(72) Inventors: Young Jae PARK, Pohang-si (KR); Seong Jun KIM, Pohang-si (KR); Hoon Kyu SHIN, Pohang-si (KR); Gil Ho LEE, Pohang-si (KR); Chae Gun LEE, Pohang-si (KR); Seung Hyun SHIN, Pohang-si (KR)

(21) Appl. No.: 18/654,150

(22) Filed: May 3, 2024

(30) Foreign Application Priority Data
May 3, 2023 (KR) 10-2023-0057678

(51) Int. Cl. H01L 29/66; H01L 29/16

(52) U.S. Cl. CPC H01L 29/66977; H01L 29/1606; H01L 29/66022

(57) ABSTRACT

Embodiments of the present disclosure relate to a quantum device including moderate fluorinated graphene and a method for fabricating the same. According to an exemplary embodiment of the present disclosure, there is provided a quantum device including moderate fluorinated graphene, the quantum device including a substrate, a first insulating layer located on the substrate, a graphene layer located on the first insulating layer, and a second insulating layer located on the graphene layer and covering a third region excluding a first region and second region on both sides of the graphene layer, in which the first region and second region of the graphene layer are formed of moderate fluorinated graphene, and a metal layer is formed on the first region and the second region, and the metal layer makes contact at some locations on the moderate fluorinated graphene.

### CROSS-REFERENCE TO RELATED APPLICATION

This application claims the benefit under 35 USC § 119 (a) of Korean Patent Application No. 10-2023-0057678, filed on May 3, 2023, in the Korean Intellectual Property Office, the entire disclosure of which is incorporated herein by reference for all purposes.

### BACKGROUND

### 1. Field

Embodiments of the present disclosure relate to a quantum device including moderate fluorinated graphene and a method for fabricating the same.

### 2. Description of Related Art

Generally, a sensitive microwave detector is an essential device in the latest fields of quantum information technology such as radio astronomy, mobile communication, radar, quantum information communication, and quantum computing. A bolometer used as the microwave detector is made of a microwave absorbing material, a material that converts absorbed microwaves into heat, and a material that converts generated heat into electrical resistance, and uses the change in electrical resistance to calculate the intensity of absorbed microwaves. However, since a conventional bolometer uses a semiconductor element such as Si or GaAs as the microwave absorption material, there was a limit to improving detection sensitivity, and accordingly, precise intensity measurement was impossible. In order to solve this problem, an ultra-thin bolometer can be fabricated based on single layer graphene rather than a semiconductor as the microwave absorbing material.

By utilizing the electronic specific heat and thermal conductivity of graphene, a highly sensitive bolometer can be fabricated by fabricating a bolometer by introducing a Josephson junction structure composed of superconductor-graphene-superconductor. To this end, it is essential to form edge contact between a superconductor and a graphene single layer. In order to make graphene contact with metal, as described in Chinese Patent CN105405965, in the past, it has been developed to expose graphene to a side by etching an active region, and then to form metal electrodes on the left and right sides of the graphene.

However, in this case, achieving contact between graphene atoms exposed on the side and the metal electrode located on the same side may pose challenges. The reason is that it is difficult to control the graphene atoms to be accurately exposed to the side through etching, and thus a case where graphene is not exposed on the side occurs, and even if graphene is exposed to the side, the metal electrode formed next to the graphene may not be deposited to contact the graphene. In order to solve this problem, there is a method of increasing the possibility that graphene is exposed to the side surface by obliquely etching an active region, but nevertheless, it may still be difficult to make proper contact with the metal electrode. Therefore, the probability of forming an edge contact with high electrical transparency between the metal electrode and graphene is low, and thus the actual fabrication yield of bolometer become low.

And, in order to insulate graphene, there is a process of fluorinating graphene with fluorine-containing plasma. However, in the process of forming fluorinated graphene, sp² or sp³ type defects or vacancy type defects occur due to plasma-induced damage during the dry etching process. These defects damage the structure of graphene and cause a decrease in quality, such as electron mobility, in graphene. Additionally, fully fluorinated graphene has insulating properties.

### CITATION LIST

### Patent Literature

China registered patent publication No. CN105405965 (2018 Sep. 25.)

### SUMMARY

Embodiments of the present disclosure are intended to provide a quantum device including moderate fluorinated graphene and a method for fabricating the same that minimize defects that occur in graphene in a process of forming fluorinated graphene and whose degree of fluorination is appropriately adjusted. Graphene, which is inevitably exposed in a process of etching a boron nitride (BN) layer, which is a protective layer formed to protect graphene, is fluorinated by gas for etching the BN layer. The fully fluorinated graphene has the properties of an insulator, but if the degree of fluorination of graphene is appropriately adjusted, contact with metal can be easily formed through a non-fluorinated region.

Also, embodiments of the present disclosure are intended to provide a quantum device including moderate fluorinated graphene and a method for fabricating the same, which can increase the yield of edge contact with high electrical transparency between a metal layer and a graphene single layer.

And, embodiments of the present disclosure are intended to provide a quantum device including moderate fluorinated graphene and a method for fabricating the same, which can increase the yield of a device fabricated even without being subjected to a complex process.

According to an exemplary embodiment of the present disclosure, there is provided a quantum device including moderate fluorinated graphene, the quantum device including a substrate, a first insulating layer located on the substrate, a graphene layer located on the first insulating layer, and a second insulating layer located on the graphene layer and covering a third region excluding a first region and second region on both sides of the graphene layer, in which the first region and second region of the graphene layer are formed of moderate fluorinated graphene, and a metal layer is formed on the first region and the second region, and the metal layer makes contact at some locations on the moderate fluorinated graphene.

Some carbon atoms in graphene included in the moderate fluorinated graphene may be fluorinated.

The third region of the graphene layer may function as a channel through which electrons move.

The first insulating layer and the second insulating layer may be boron nitride (BN).

The graphene layer may be single layer graphene or few layer graphene.

According to another exemplary embodiment of the present disclosure, there is provided a method for fabricating a quantum device including moderate fluorinated graphene, the method including stacking a first insulating layer, a graphene layer, and a second insulating layer in that order on a substrate, forming a mask pattern on the second insulating layer, exposing a first region and second region on both sides of the graphene layer by etching the second insulating layer along the mask pattern using etching gas, forming the first region and second region of the graphene layer into moderate fluorinated graphene by adjusting the exposure time and plasma intensity of the etching gas, and forming a metal layer on each of the first region and the second region of the graphene layer.

Some carbon atoms in graphene included in the moderate fluorinated graphene may be fluorinated.

A value obtained by multiplying the exposure time and plasma intensity of the etching gas may be 100 J or less.

A third region of the graphene excluding the first region and second region, may function as a channel through which electrons move.

The first insulating layer and the second insulating layer may be boron nitride (BN).

The graphene layer may be single layer graphene or few layer graphene.

The etching gas may be fluorinatable gas.

### BRIEF DESCRIPTION OF THE DRAWINGS

FIGS. 1 to 7 are diagrams illustrating a process of fabricating a quantum device including an edge contact according to an embodiment of the present invention.

FIG. 1 is a diagram illustrating stacking of a first insulating layer, a graphene layer, and a second insulating layer in that order on a substrate.

FIG. 2 is a diagram illustrating a state in which a mask material is deposited on the second insulating layer.

FIG. 3 is a diagram illustrating a mask pattern formed through lithography on the mask material of FIG. 2.

FIG. 4 is a diagram illustrating etching the second insulating layer through etching gas.

FIG. 5 is a diagram illustrating that both exposed regions of the graphene layer are formed of fluorinated graphene by etching gas.

FIG. 6 is a diagram illustrating a state in which a metal layer is formed on the first region and second region which are moderate fluorinated graphene.

FIG. 7 is a diagram illustrating a finally formed quantum device according to an embodiment of the present disclosure.

FIG. 8 is a graph illustrating that defects occurring in graphene occur in a fluorination process.

FIG. 9 is a diagram illustrating that a process of plasma treatment is performed with the substrate turned over.

FIG. 10A to 10C are a graph illustrating a ratio I_{D}/I_{D′} of the intensity of a D peak to the intensity of a D′ peak and diagrams illustrating defect types of graphene.

FIG. 11 is a graph illustrating that a ratio I_{D}/I_{G} of the intensity of the D peak to the intensity of a G peak changes according to a product of the plasma intensity and exposure time.

### DETAILED DESCRIPTION

Hereinafter, a specific embodiment of the present disclosure will be described with reference to the drawings. The following detailed description is provided to aid in a comprehensive understanding of the methods, apparatus and/or systems described herein. However, this is illustrative only, and the present disclosure is not limited thereto.

In describing the embodiments of the present disclosure, when it is determined that a detailed description of related known technologies may unnecessarily obscure the subject matter of the present disclosure, a detailed description thereof will be omitted. Additionally, terms to be described later are terms defined in consideration of functions in the present disclosure, which may vary according to the intention or custom of users or operators. Therefore, the definition should be made based on the contents throughout this specification. The terms used in the detailed description are only for describing embodiments of the present disclosure, and should not be limiting. Unless explicitly used otherwise, expressions in the singular form include the meaning of the plural form. In this description, expressions such as “comprising” or “including” are intended to refer to certain features, numbers, steps, actions, elements, some or combination thereof, and it is not to be construed to exclude the presence or possibility of one or more other features, numbers, steps, actions, elements, some or combinations thereof, other than those described.

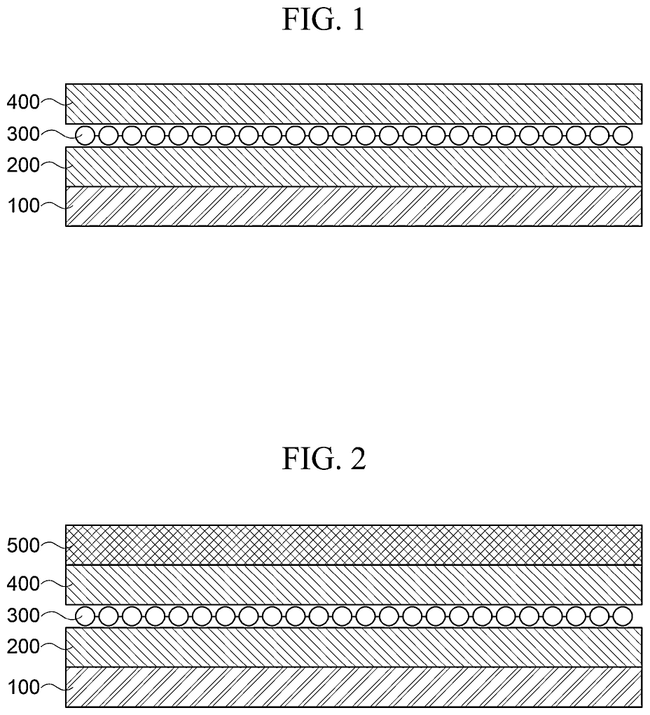

FIGS. 1 to 7 are diagrams illustrating a process of fabricating a quantum device including moderate fluorinated graphene according to an embodiment of the present invention.

FIG. 1 is a diagram illustrating stacking of a first insulating layer 200, a graphene layer 300, and a second insulating layer 400 in that order on a substrate 100.

Referring to FIG. 1, the substrate 100 may be silicon Si, or may also be selected from sapphire, SiC, Ga₂O₃, and diamond. First, the first insulating layer 200 may be stacked on the substrate 100 using a transfer method. The transfer may be wet transfer or dry transfer, and a thickness of the first insulating layer 200 may be 10 to 30 nm. The first insulating layer 200 may be hexagonal boron nitride (hBN). The hBN has a structure similar to graphite and has excellent electrical insulation properties, and thus may be suitable as the first insulating layer 200.

The graphene layer 300 may be stacked on the first insulating layer 200 by a transfer method. The transfer for the graphene layer 300 may be wet transfer or dry transfer, and the graphene layer 300 may be single layer or few layer graphene.

The second insulating layer 400 may be stacked on the graphene layer 300 by a transfer method. The transfer for the second insulating layer 400 may also be wet transfer or dry transfer, and the thickness of the second insulating layer 400 may be 10 to 60 nm. The second insulating layer 400 may also be the hBN.

FIG. 2 is a diagram illustrating a state in which a mask material 500 is deposited on the second insulating layer 400.

Referring to FIG. 2, the mask material 500 may be deposited on the second insulating layer 400. The mask material 500 may be selected from photoresist (PR), e-beam resist, and silicon dioxide (SiO₂).

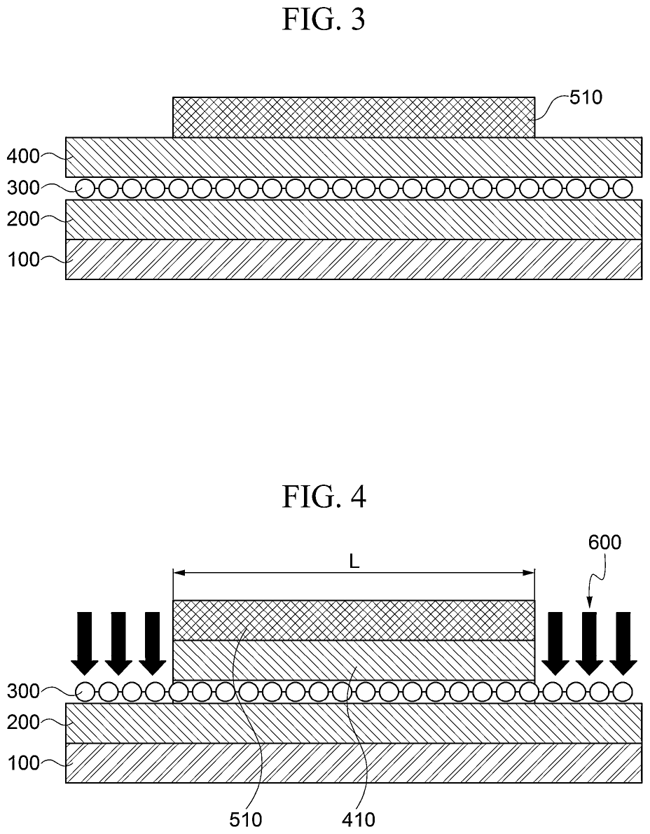

FIG. 3 is a diagram illustrating a mask pattern 510 formed through lithography on the mask material 500 of FIG. 2.

Referring to FIG. 3, the mask pattern 510 may be formed on the mask material 500 to expose a portion to be etched through lithography. In order to remove both sides of the second insulating layer 400 through etching, the second insulating layer 400 may be exposed on both sides of the mask pattern 510. Depending on the type of mask material 500, the mask pattern 510 may be formed through photolithography or e-beam lithography.

FIG. 4 is a diagram illustrating etching the second insulating layer 400 using etching gas 600.

Referring to FIG. 4, both sides of the second insulating layer 400 exposed by the mask pattern 510 may be etched. The etching gas 600 may preferably be CF₄. The reason why CF₄ is used as the etching gas 600 is because CF₄ etches hexagonal boron nitride hBN, which is the second insulating layer, whereas CF₄ does not etch the graphene layer 300 located below the second insulating layer 400. As the etching gas 600, other fluorinated gas (fluorinatable gas) such as XeF₂ or HF may be used instead of CF₄. Etching may be performed by forming a plasma state by supplying energy to the etching gas 600, and then etching the second insulating layer 400 in the plasma state. The graphene layer 300 acts as an etching stop layer, so that the first insulating layer 200 located below the graphene layer 300 is not etched.

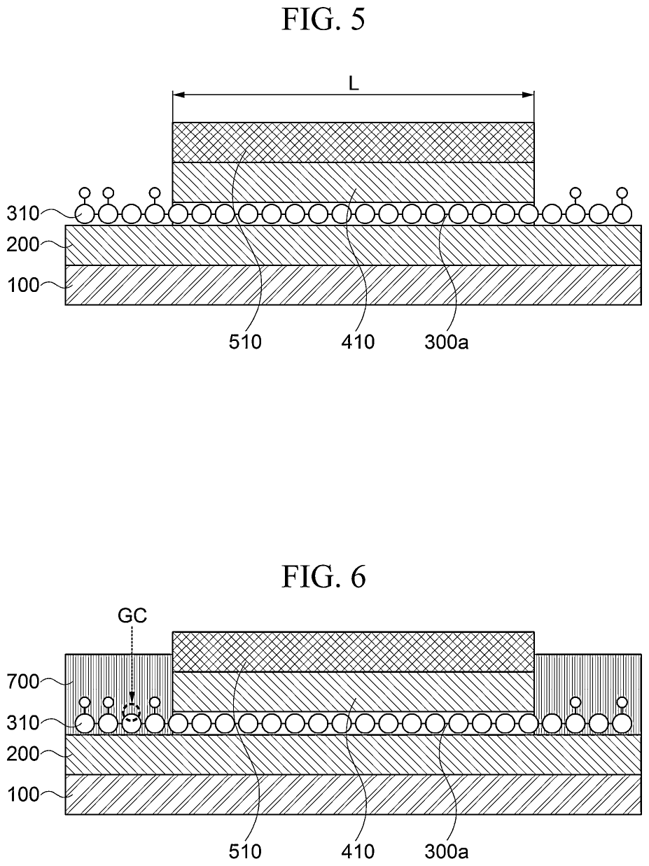

FIG. 5 is a diagram illustrating that both exposed regions of the graphene layer 300 are formed of fluorinated graphene by the plasmatized etching material 600.

Referring to FIG. 5, when the second insulating layer is etched by CF₄, which is the etching gas 600 and the etching gas 600 comes into contact with the graphene layer 300, fluorine (F) in the etching gas and graphene in the graphene layer 300 may be chemically bonded to form fluorinated graphene 310 and 320. Here, the regions of the graphene layer made of fluorinated graphene may be used as a first region 310 and a second region 320, and the remaining regions may be used as a third region 300a. That is, the third region 300a may still be made of single layer graphene. However, the degree of fluorination in the graphene layer may be adjusted by controlling the etching conditions. This may be referred to as moderate fluorinated graphene. In the moderate fluorinated graphene, only some carbon atoms in the graphene are fluorinated by being bonded with fluorine atoms, and other carbon atoms may exist in a non-fluorinated state. As a result, the first region 310 and the second region 320, which are moderate fluorinated graphene, may be partially insulated, and the third region 300a may be a conductive layer.

The method of forming the moderate fluorinated graphene here may be to prevent damage to the graphene. If the fluorine plasma intensity and the exposure time are increased in the etching process for the second insulating layer 400, sp²-type or vacancy-type defects may occur in the exposed graphene, which may deteriorate the quality of graphene. In order to solve this problem, the moderate fluorinated graphene with minimal damage may be formed by performing fluorination under conditions that can minimize defects in graphene by controlling the degree of fluorination.

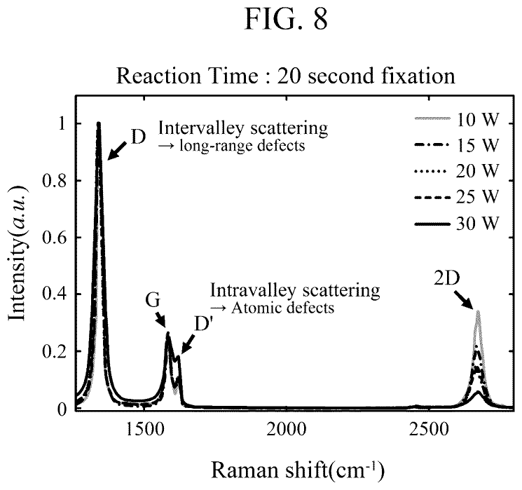

FIG. 8 is a graph illustrating that defects occurring in graphene occur in a fluorination process.

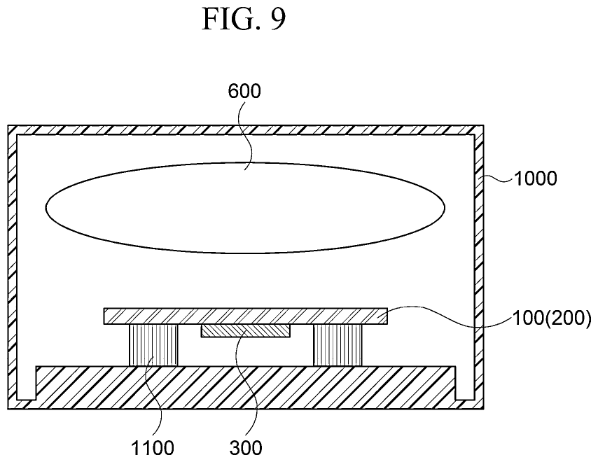

Referring to FIG. 8, in the graph, the G peak and the 2D peak are peaks that represent the general properties of graphene, and the D peak and D′ peak may occur due to defects occurring in the fluorination process. According to the graph in FIG. 8, as the plasma intensity (10W to 30W) increases, the intensity of the D peak and D′ peak corresponding to graphene defects increases. Accordingly, in order to lower the plasma intensity, as illustrated in FIG. 9, the substrate may be turned over so that the graphene layer is located on a side opposite to the plasma with the substrate as a reference, in order to prevent plasma from being directly exposed to the graphene.

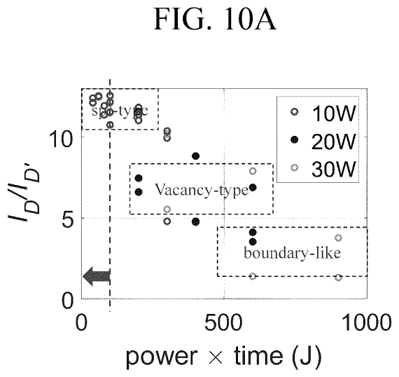

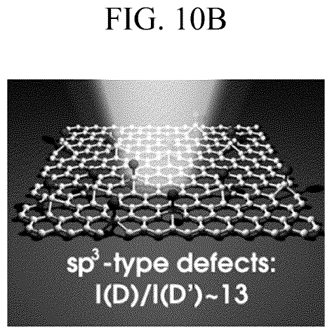

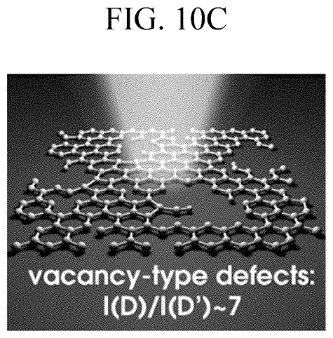

FIG. 10A to 10C is a graph illustrating a ratio I_{D}/I_{D′} of the intensity of the D peak to the intensity of the D′ peak and a diagram illustrating defect types of graphene.

Referring to FIG. 10A is a graph illustrating that a ratio I_{D}/I_{D′} of the intensity of the D peak to the intensity of the D′ peak changes according to a product of the plasma intensity and exposure time, and this may indicate information about the defect type of graphene. As a value obtained by multiplying the plasma intensity and the exposure time increases, defects in graphene may appear as sp³ type, vacancy type, or boundary-like. The sp³ type defects may be defects in which a bonding relationship between carbon atoms is twisted, as illustrated in FIG. 10B. In the vacancy type defects, an empty space may occur in graphene, as shown in FIG. 10C. In the boundary-like defects, a significant portion of graphene may be etched to form a boundary. In this way, as the plasma intensity and exposure time increase, the degree of defects in graphene may become more severe. Therefore, it is necessary to control the plasma intensity and exposure time that can prevent these defects from occurring. According to FIG. 10A, it is preferable that a value obtained by multiplying the plasma intensity by the exposure time is 100 J or less.

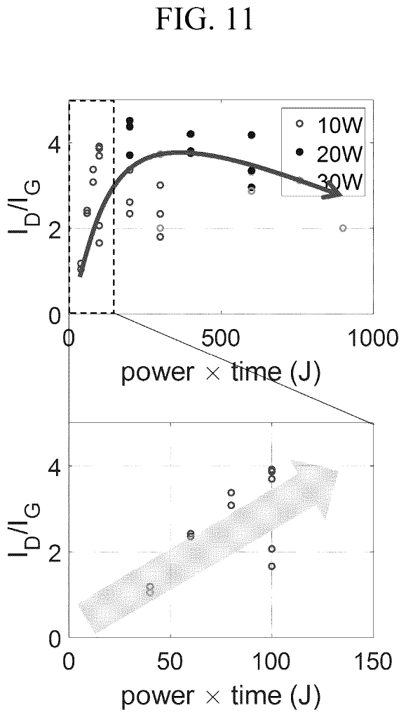

FIG. 11 is a graph illustrating that a ratio I_{D}/I_{G} of the intensity of the D peak to the intensity of the G peak changes according to the product of plasma intensity and exposure time.

Referring to FIG. 11, the ratio I_{D}/I_{G} of the intensity of the D peak to the intensity of the G peak indicates the degree of fluorination of graphene. According to the graph of FIG. 11, in the range where the product of the plasma intensity and exposure time is 0 to 150 J, the degree of fluorination increases as the value obtained by multiplying the plasma intensity and the exposure time increases. Therefore, as described above, it can be seen that the degree of fluorination can be adjusted by controlling the value obtained by multiplying the plasma intensity and the exposure time in a range, which is equal to or less than 100 J, in which defects in graphene can be prevented.

FIG. 6 is a diagram illustrating a state in which a metal layer 700 is formed on the first region 310 and the second region 320 which are moderate fluorinated graphene.

Referring to FIG. 6, the metal layer 700 is formed on the moderate fluorinated graphene, and the third region 300a, which is graphene, may be adjacent to the metal layer 700. The metal layer 700 is formed for electrical contact, and may be a single element containing metals such as titanium (Ti), aluminum (Al), nickel (Ni), and gold (Au), or an alloy thereof. The metal layer 700 may serve as an electrode located on both sides of the third region 300a.

A graphene contact (GC) may be formed between the metal layer 700 and the graphene layer constituting the third region 300a. In the drawing, the metal layer 700 appears to be in contact with the first region 310 and the second region 320, which are formed of moderate fluorinated graphene, which is a partial insulating layer, and is not in direct contact with the third region 300a. Of the moderate fluorinated graphene in the first region 310 and the second region 320, electrons may move toward the graphene that is not bonded to fluorine atoms, thereby forming the graphene contact (GC). Accordingly, electrons may move between the metal layer 700 and the graphene side of the third region 300a.

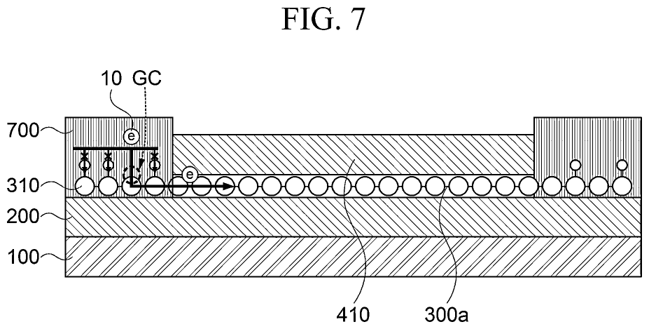

FIG. 7 is a diagram illustrating a finally formed quantum device according to an embodiment of the present disclosure.

Referring to FIG. 7, the final quantum device may be formed by removing the mask pattern 510, which is the uppermost layer, in the state illustrated in FIG. 6. The mask pattern 510 may be removed through etching for removing the mask pattern 510.

FIG. 7 shows electrons 10 moving from the metal layer 700 to the third region 300a, C of the graphene layer by the graphene contact (GC). As described above, electrons may move through non-fluorinated graphene of the first region 310 and the second region 320, which are moderate fluorinated graphene, to the third region 300a, which is a graphene layer between the first insulating layer 200 and the etched second insulating layer 400. As a result, the graphene contact GC may be formed between the metal layer 700 located on the first region 310, A and second region 320, B and the third regions 300a, C which is formed of graphene. Accordingly, the electrons 10 of the metal layer 700 may move to the third region 300a, C, and the third region may serve as an electron channel. This graphene contact (GC) may achieve the effect of providing a point contact rather than a surface contact between the metal layer 700 and the graphene layer 300a.

Through this, it is possible to form a quantum device that can detect a change in electrical resistance occurring in graphene in a very short time by the Josephson junction structure formed between the superconducting metal layer on both sides and the third region, which is the graphene layer. The origin of superconductivity is Cooper pairs. In order to generate the Cooper pairs, electron pairs with energies corresponding to the Fermi level are required. However, when photons pass through the graphene, the temperature of electrons increases, which hinders the formation of Cooper pairs. Ultimately, the energy of photons reduces superconductivity. This can be directly confirmed by observing changes in the critical current of Josephson junctions. These quantum devices can be embedded within a microwave resonator and serve as the bolometer with high sensitivity.

As illustrated in FIG. 7, the finally formed quantum device may include the substrate 100, the first insulating layer 200 located on the substrate 100, the third region 300a, which is the graphene layer located on the first insulating layer 200, and a second insulating layer 410 located on the third region 300a, which is the graphene layer. And, the first region 310 and the second region 320 located on both sides of the third region 300a are formed of moderate fluorinated graphene, and the metal layer 700 that functions as an electrode may be formed on the first region 310 and the second region 320.

Here, the first insulating layer 200 and the second insulating layer 410 may be hexagonal boron nitride (hBN), and the third region 300a, which is the graphene layer, may be a single layer.

In this way, according to an embodiment of the present invention, it is possible to form the graphene contact and minimize the occurrence of defects in the graphene due to fluorination in the process of fluorinating graphene. Such defect prevention is possible by adjusting the intensity the fluorine plasma and the exposure time, thereby making it possible to fabricate a quantum device that can form the graphene contact while securing a necessary degree of insulation.

In addition, according to an embodiment of the present disclosure, the process yield of the contact between the metal layer 700 and the graphene layer 300a can be greatly improved compared to that of the related art. Conventionally, the edge contact was formed as a physical structure, but it was difficult to control the process so as to ensure proper contact between a very fine structure such as graphene and metal. On the other hand, according to an embodiment of the present disclosure, since non-fluorinated graphene is formed among the fluorinated graphene, which is an insulating layer, to form the graphene contact between the electrode metal and the moderate fluorinated graphene, the contact yield can be greatly increased.

Additionally, according to an embodiment of the present disclosure, contact resistance can be reduced by increasing the contact yield.

According to embodiments of the present disclosure, the quantum device including moderate fluorinated graphene and the method for fabricating the same, which can minimize defects occurring in graphene in the process of forming fluorinated graphene, are provided.

According to embodiments of the present disclosure, the quantum device including moderate fluorinated graphene and the method for fabricating the same, which can increase the yield of edge contact with high electrical transparency between the metal layer and the graphene single layer, are provided.

According to an embodiment of the present disclosure, the quantum device including moderate fluorinated graphene and the method for fabricating the same, which can increase the yield of the device fabricated even without being subjected to a complex process, are provided.

Although representative embodiments of the present disclosure have been described in detail, a person skilled in the art to which the present disclosure pertains will understand that various modifications may be made thereto within the limits that do not depart from the scope of the present disclosure. Therefore, the scope of rights of the present disclosure should not be limited to the described embodiments, but should be defined not only by claims set forth below but also by equivalents to the claims.

What is claimed is:

1. A quantum device including moderate fluorinated graphene, comprising:
a substrate;
a first insulating layer located on the substrate;
a graphene layer located on the first insulating layer; and
a second insulating layer located on the graphene layer and covering a third region excluding a first region and second region on both sides of the graphene layer, wherein
the first region and second region of the graphene layer are formed of moderate fluorinated graphene, and
a metal layer is formed on the first region and the second region, and the metal layer makes contact at some locations on the moderate fluorinated graphene.

2. The quantum device of claim 1, wherein
some carbon atoms in graphene included in the moderate fluorinated graphene are fluorinated.

3. The quantum device of claim 1, wherein
the third region of the graphene layer functions as a channel through which electrons move.

4. The quantum device of claim 1, wherein
the first insulating layer and the second insulating layer are boron nitride (BN).

5. The quantum device of claim 1, wherein
the graphene layer is single layer graphene or few layer graphene.

6. A method for fabricating a quantum device including moderate fluorinated graphene, the method comprising:
stacking a first insulating layer, a graphene layer, and a second insulating layer in that order on a substrate;
forming a mask pattern on the second insulating layer;
exposing a first region and second region on both sides of the graphene layer by etching the second insulating layer along the mask pattern using etching gas;
forming the first region and second region of the graphene layer into moderate fluorinated graphene by adjusting the exposure time and plasma intensity of the etching gas; and
forming a metal layer on each of the first region and the second region of the graphene layer.

7. The method of claim 6, wherein
some carbon atoms in graphene included in the moderate fluorinated graphene are fluorinated.

8. The method of claim 6, wherein
a value obtained by multiplying the exposure time and plasma intensity of the etching gas is 100 J or less.

9. The method of claim 6, wherein
a third region of the graphene excluding the first region and second region functions as a channel through which electrons move.

10. The method of claim 6, wherein
the first insulating layer and the second insulating layer are boron nitride (BN).

11. The method of claim 6, wherein
the graphene layer is single layer graphene or few layer graphene.

12. The method of claim 6, wherein
the etching gas is fluorinatable gas.
